(19) United States
(12) Patent Application Publication
(10) Pub. No.: US 2007/0252270 A1
(43) Pub. Date: Nov. 1, 2007

(54) Circuit Apparatus

(75) Inventors: Yoh Takano, Ogaki-city (JP); Ryosuke Usui, Ichinomiya-City (JP); Makoto Murai, Anpachi-Gun (JP)

Correspondence Address: FISH & RICHARDSON P.C., P.O. BOX 1022, MINNEAPOLIS, MN, 55440-1022, US

(73) Assignee: Sanyo Electric Co., Ltd., Osaka (JP)

(21) Appl. No.: 11/740,639

(22) Filed: Apr. 26, 2007

(30) Foreign Application Priority Data
Apr. 27, 2006 (JP) 2006-123772
Apr. 13, 2007 (JP) 2007-105777

(51) Int. Cl. H01L 23/34

(52) U.S. Cl. 257/723

(57) ABSTRACT

Heat from a circuit element is effectively conducted to a metal substrate so that reliability of a circuit apparatus is improved. A circuit element is configured such that a wiring layer is formed on a metal substrate. Power devices are mounted on the wiring layer in addition to a circuit element constituting a control unit. Steps are formed by grooves of a predetermined pattern on the primary surface of the metal substrate. High heat dissipation circuit elements generating a relatively large amount of heat (i.e., power devices) are mounted above projections on the metal substrate. Low heat dissipation circuit elements generating a relatively small amount of heat are mounted above the depression in the metal substrate. In other words, the distance between the power device which generates a relatively large amount of heat and the metal substrate opposite to the device is smaller than the distance between the circuit element of the control unit which generates a relatively small amount of heat and the metal substrate opposite to the element.

### CROSS-REFERENCE TO RELATED APPLICATIONS

This application is based upon and claims the benefit of priority from the prior Japanese Patent Application No. 2006-123772, filed Apr. 27, 2006, and Japanese Patent Application No. 2007-105777, filed Apr. 13, 2007, the entire contents of which are incorporated herein by reference.

### BACKGROUND OF THE INVENTION

1. Field of the Invention

The present invention relates to a circuit apparatus and, more particularly, to a circuit apparatus in which a circuit element is mounted on a metal substrate.

2. Description of the Related Art

The advancement in performance and functions of large scale integrated circuits (LSIs) in recent years demand increased power consumption. As the size of electronic appliances is reduced, size reduction, higher density and multi-layer structure in mounting substrates are called for. As a result of associated increase in power consumption (heat density) per unit volume of a circuit substrate, there is a growing need for measures for heat dissipation.

In this background, metal substrates characterized by high heat dissipation are recently used as substrates in circuit apparatuses so that circuit elements such as LSIs are mounted on the metal substrates.

FIG. 11 is a sectional view schematically showing the structure of a related-art circuit apparatus according to the related art. As shown in FIG. 11, a resin layer 102, which functions as an insulating layer and in which a silica (SiO₂) filler is added, is formed on a metal substrate 101 formed of aluminum. An IC chip 104 using a silicon substrate is mounted on a predetermined area in the resin layer 102 via an adhesive layer 103 of resin. A metal wiring 105 of copper is formed in an area on the resin layer 102 at a distance from the end of the IC chip 104, the adhesive layer 103 being interposed between the metal wiring 105 and the resin layer 102. The metal wiring 105 and the metal substrate 101 are insulated from each other by the resin layer 102. The metal wiring 105 and the IC chip 104 are electrically connected by a wire 106.

In the related-art circuit apparatus shown in FIG. 11, the metal substrate 101 of aluminum is used. The IC chip 104 is mounted on the metal substrate 101 via the insulating layer 102. In this way, a large amount of heat generated from the IC chip 104 can be dissipated by the metal substrate 101.

A requirement that has arisen recently is to efficiently dissipate heat from circuit elements (IC chips) to a metal substrate.

### SUMMARY OF THE INVENTION

In this background, a general purpose of the present invention is to efficiently conduct heat from a circuit element to a metal substrate and to improve heat dissipation in a circuit apparatus accordingly.

An embodiment of the present invention relates to a circuit apparatus. The circuit apparatus comprises: a metal substrate the primary surface of which is provided with a step; a conductive layer provided on the primary surface of the metal substrate via an insulating layer; and a plurality of circuit elements provided on the conductive layer and generating different amounts of heat, wherein the distance between the high heat dissipation circuit element generating a relatively large amount of heat and an area in the metal substrate opposite to the high heat dissipation circuit element is smaller than the distance between the low heat dissipation circuit element generating a relatively small amount of heat and an area in the metal substrate opposite to the low heat dissipation circuit element.

According to this embodiment, heat generated in the high heat dissipation element is efficiently conducted to the metal substrate because the distance between the high heat dissipation circuit element and the metal substrate is comparatively small. Consequently, heat dissipation of the circuit apparatus is improved.

In the circuit element of the embodiment, the number of wiring layers, each comprising a conductive layer and an insulating layer formed between the high dissipation circuit element and the metal substrate opposite to the high heat dissipation circuit element, may be smaller than the number of wiring layers each comprising a conductive layer and an insulating layer formed between the low heat dissipation circuit element and the metal substrate opposite to the low heat dissipation circuit element.

In the circuit element of the embodiment, the surface of the metal substrate may be roughened.

According to this embodiment, the area of contact between the metal substrate and the insulating layer is increased. In this way, the intimacy of contact between the metal substrate and the insulating layer is improved and the likelihood of exfoliation of the insulating layer from the metal substrate is reduced. Consequently, a circuit apparatus is provided in which the likelihood of exfoliation of the insulating layer from the metal substrate is reduced and heat dissipation is improved.

In the circuit element of the embodiment, the high heat dissipation circuit element may be a power device for supplying power to a load and the low heat dissipation element may control the output of the power device or may drive the power device. It is to be noted that any arbitrary combination or rearrangement of the above-described structural components and so forth are all effective as and encompassed by the present embodiments. Moreover, this summary of the invention does not necessarily describe all necessary features so that the invention may also be sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a sectional view showing the schematic sectional structure of a circuit apparatus according to a first embodiment;

FIGS. 2A-2E are sectional views showing the process for fabricating the circuit apparatus according to the first embodiment;

FIGS. 3A-3E are sectional views showing the process for fabricating the circuit apparatus according to the first embodiment;

FIGS. 4A-4D are sectional views showing the process for fabricating the circuit apparatus according to the first embodiment;

FIGS. 5A-5C are sectional views showing the process for fabricating the circuit apparatus according to the first embodiment;

FIG. 6 is a sectional view showing the schematic sectional structure of a circuit apparatus according to a variation of the first embodiment;

FIGS. 7A-7E are sectional views for illustrating the process for fabricating the circuit apparatus according to the variation of the first embodiment;

FIG. 8 is a top view showing the layout of a control unit and a power unit of a circuit apparatus according to a second embodiment;

FIG. 9 is an equivalent circuit diagram related to the control unit and the power unit of the circuit apparatus according to the second embodiment;

FIG. 10 is a sectional view showing the schematic sectional structure of the circuit apparatus according to the second embodiment; and

FIG. 11 is a sectional view schematically showing the structure of a related-art circuit apparatus.

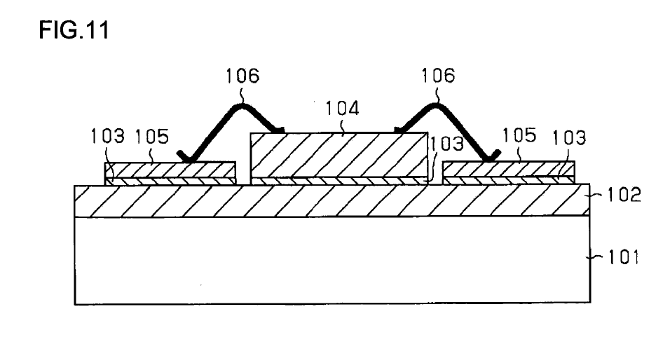

### DETAILED DESCRIPTION OF THE INVENTION

The invention will now be described by reference to the preferred embodiments. This does not intend to limit the scope of the present invention, but to exemplify the invention.

A description will be given below of embodiments of the present invention with reference to the drawings. In the figures, like numerals represent like constituting elements, and the description thereof is omitted appropriately.

### First Embodiment

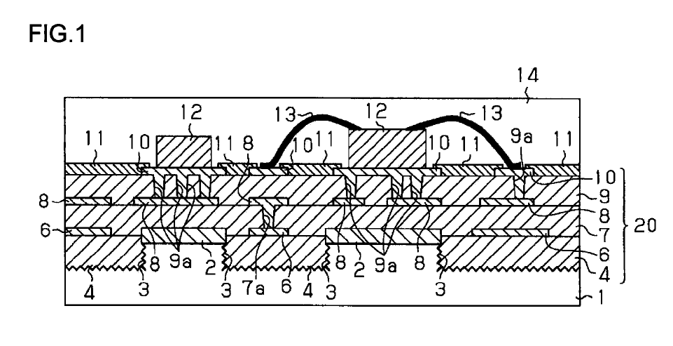

FIG. 1 is a schematic sectional view of a circuit apparatus provided with a metal substrate according to a first embodiment. A description will be given of the circuit apparatus according to this embodiment with reference to FIG. 1.

The circuit apparatus according to this embodiment is provided with a metal substrate 1, a heat transfer layer 2, a wiring layer 20, a solder resist layer 11, circuit elements 12, wires 13 and a sealing resin layer 14, the wiring layer 20 comprising a plurality of conductive layers 6, 8 and 10 and insulating layers 4, 7 and 9.

A copper (Cu) substrate having a thickness of about 1.5 mm is used as the metal substrate 1. The metal substrate 1 is provided with grooves 3 formed by the heat transfer layer 2 described later and the metal substrate 1. Each of the grooves 3 is formed outside an area in the metal substrate 1 where the heat transfer layer 2 is formed, so as to surround the heat transfer layer 2. The depth of the grooves 3 is about, for example, 100 μm. The interior surfaces (bottom and sides) of the grooves 3 in the metal substrate 1 are roughened. The arithmetic average roughness Ra of the metal substrate 1 with the roughened surfaces is about 0.3 μm-10 μm.

The heat transfer layer 2 is provided in a part of the metal substrate 1 and is selectively formed below the area where the circuit element 12 is mounted, The heat transfer layer 2 is partitioned such that the circuit element is mounted in each resultant area. The layer 2 is surrounded by the grooves 3. The thickness of the heat transfer layer 2 is about, for example, 50 μm. The heat transfer layer 2 is formed of a metal material having higher heat conductivity than the metal substrate 1. Since the heat transfer layer 2 is provided directly on the metal substrate 1, heat from the heat transfer layer 2 is directly conducted to the metal substrate 1. This ensures high heat dissipation effect and excellent heat dissipation from the circuit apparatus.

The wiring layer 20 is formed on the metal substrate 1 and the heat transfer layer 2, which define the grooves 3. The layer 20 is of a three-layer structure in which the insulating layers 4, 7 and 9 and the conductive layers 6, 8 and 10 are alternately stacked on each other.

The specific structure of the wiring layer 20 is as follows.

The insulating layer 4 and the conductive layer 6 in the first layer in the stack are both formed in the groove 3 formed by the metal substrate 1 and the heat transfer layer 2. More specifically, the insulating layer 4 is formed in the groove 3 of the metal substrate 1. The conductive layer 6 (the lowermost conductive layer) in the first layer in the stack is formed on the insulating layer 4. The conductive layer 6 is an example of the “first conductive layer” of the present invention.

A film primarily composed of epoxy resin is employed to form the insulating layer 4. The thickness of the layer 4 is about, for example, 80 μm. Further, a filler having a diameter of about 4 μm (maximum grain size=12 μm) is added to the insulating layer 4 in order to improve the heat conductivity of the insulating layer 4 primarily composed of epoxy resin. Alumina (Al₂O₃) or silica (SiO₂) may be used as the filler. The volume filling ratio of the filler is about 60-80%. The heat conductivity of epoxy resin to which the filler such as alumina or silica is added is about 2 W/(m×k), which is higher than the heat conductivity (about 0.6 W/(m×k)) of epoxy resin to which the filler is not added.

A metal such as copper or aluminum is employed to form the conductive layer 6. The thickness of the layer 6 is about 20 μm.

The material having the same composition as the insulating layer 4 is employed to form the insulating layer 7 in the second layer in the stack. The layer 7 is formed to cover the conductive layer 6 and the heat transfer layer 2. The thickness of the insulating layer 7 is about 80 μm.

The same material forming the conductive layer 6 is employed to form the conductive layer 8 in the second layer in the stack. The layer 8 is formed on the insulating layer 7. The conductive layer 6 and the conductive layer 8 are connected to each other via a via hole 7a provided at a predetermined location. The thickness of the conductive layer 8 is about 15 μm. The conductive layer 8 is an example of the “second conductive layer” of the present invention.

The material having the same composition as the insulating layer 4 is employed to form the insulating layer 9 in the third layer in the stack. The layer 9 is formed to cover the conductive layer 8. The thickness of the insulating layer 9 is about 80 μm.

The material having the same composition as the conductive layer 6 is employed to form the conductive layer 10 in the third layer in the stack. The layer 10 is formed on the insulating layer 9. The conductive layer 8 and the conductive layer 10 are connected to each other via a via hole 9a provided at a predetermined location. The thickness of the conductive layer 10 is about 15 μm.

The wiring layer 20 of a three-layer structure is formed as described above.

The solder resist layer 11 is formed to cover the wiring layer 20 (insulating layer 9 and the conductive layer 10) and is formed to create openings at predetermined areas of the conductive layer 10 where the circuit elements are mounted or wires are connected. The solder resist layer 11 functions as a protective film for the wiring layer 20. The thickness of the solder resist layer 11 is about 20 μm.

The circuit element 12 is, for example, a semiconductor element such as an IC chip or an LSI chip, or a passive element such as a capacitor or a resistor. The circuit element 12 is mounted on the conductive layer 10 via an adhesive layer (not shown) formed of solder, silver paste or the like so as to be fitted in the opening.

For example, gold wires are employed to form the wires 13 for electrical connection between the circuit elements 12 mounted on the wiring layer 20 and the conductive layer 10.

The sealing resin layer 14 seals the circuit element 12 mounted on the wiring layer 20 and protects the circuit element 12 from conditions external to the apparatus. For example, thermosetting insulating resin such as epoxy resin is used to form the sealing resin layer 14.

(Method of Fabrication)

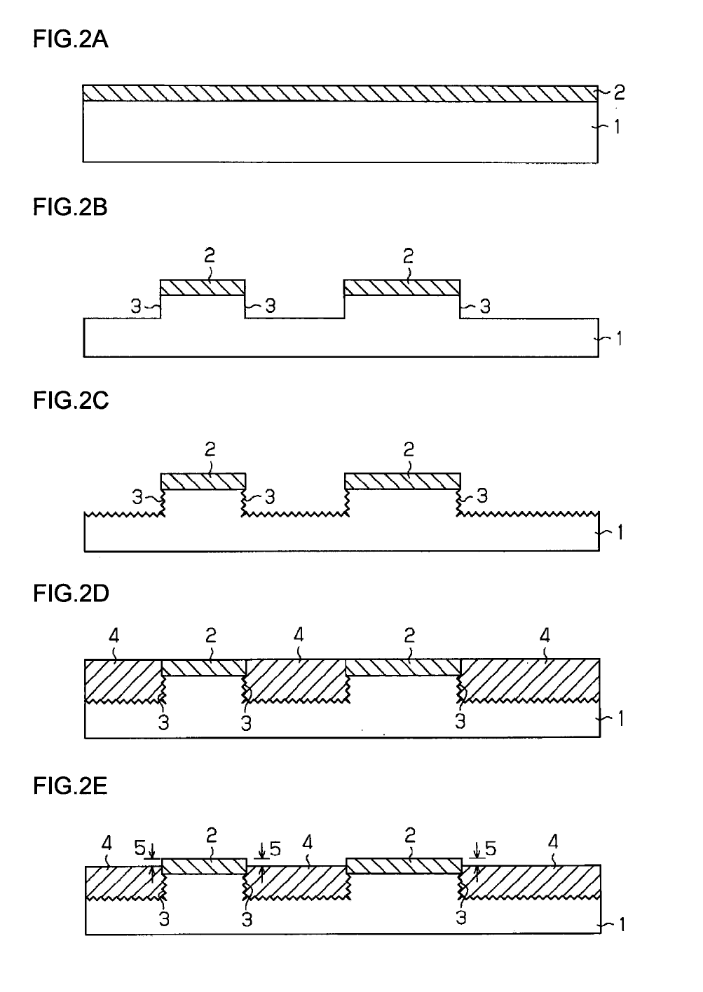

FIGS. 2A through 5C are sectional views for illustrating the process for fabricating the circuit apparatus according to the first embodiment shown in FIG. 1. A description will now be given of the process for fabricating the circuit apparatus according to this embodiment with reference to FIGS. 1 through 5C.

As shown in FIG. 2A, a stack structure comprising the metal substrate 1 having a thickness of about 1.5 mm and the heat transfer layer 2 having a thickness of about 50 μm is prepared. While the heat transfer layer 2 as illustrated is directly provided on the metal substrate 1, an adhesive layer having high heat conductivity may be provided in between.

Lithography is used to form a patterning resist film (not shown) on the surface of the heat transfer layer 2 such that openings are created in areas where the grooves 3 are formed as shown in FIG. 2B. The heat transfer layer 2 is then etched by using the patterning resist film as a mask. Etching is continued so as to remove the metal substrate 1 to a depth of about 50 μm. Finally, the patterning resist film is removed. This results in the grooves 3 of a depth of about 100 μm formed by the heat transfer layer 2 and the metal substrate 1. The heat transfer layer 2 is partitioned such that the circuit element is mounted in each resultant area. Each of the grooves 3 is formed outside an area in the metal substrate 1 where the heat transfer layer 2 is formed, so as to surround the heat transfer layer 2.

As shown in FIG. 2C, the surface of the metal substrate 1 is roughened by, for example, wet etching. By using sulfuric acid as a chemical to wet-etch the substrate formed of copper, the surface is turned into a roughened surface with minute irregularities of a size commensurate with the grain size of crystals. In this way, the interior surfaces of the grooves 3 in the metal substrate 1 are roughened with minute irreguralities formed thereon. As described above, the arithmetic average roughness Ra of the metal substrate 1 with the roughened surfaces is about 0.3 μm-10 μm. The surface roughness Ra of the metal substrate 1 can be measured with a surface measuring probe. The chemical treatment does not roughen the surface of the heat transfer layer 2.

As shown in FIG. 2D, the surface of the assembly is coated with a film comprising epoxy resin and including a certain percentage of filler. The grooves 3 are then filled by resin by means of scraping means such as a squeegee so as to form the insulating layer 4 in the first layer in the stack. The thickness of the insulating film 4 is about, for example, 100 μm.

As shown in FIG. 2E, dry etching is used to remove about 20 μm of the insulating layer 4 from its surface so as to form a step 5 of a height equal to the thickness of the conducting layer 6 to be formed on the insulating layer 4. As a result, the thickness of the insulating layer 4 in the groove 3 is about 80 μm.

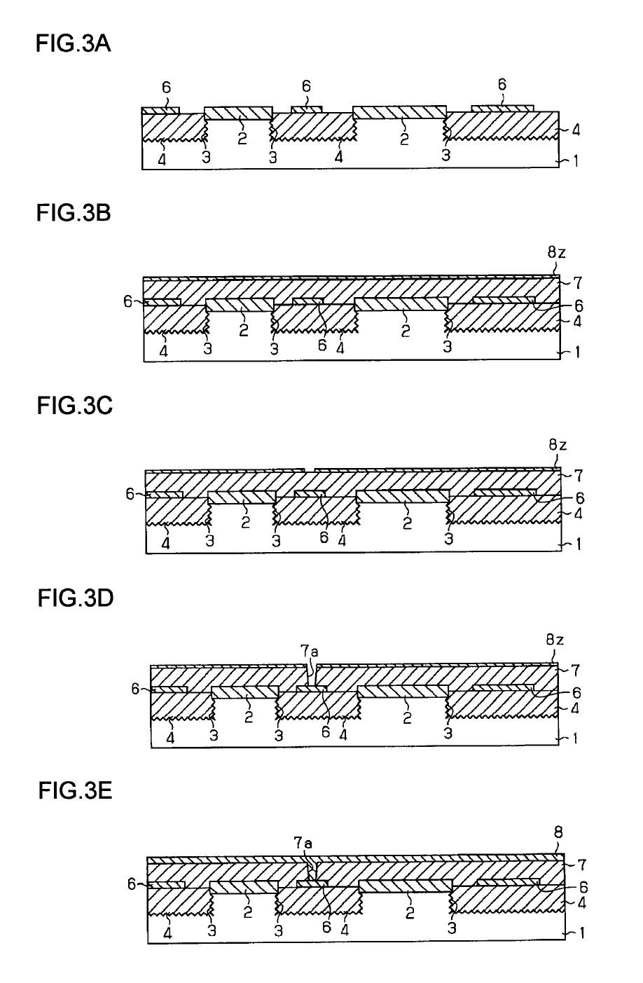

Subsequently, as shown in FIG. 3A, a copper (Cu) thin film (not shown) of a thickness of about 0.5 μm is formed by electroless plating. A patterning resist film (not shown) is then formed such that an opening is created in an area where the conductive layer 6 is formed. The conductive layer 6 of copper (Cu) is then formed by electroplating in the opening formed in the patterning resist film. The thickness of the conductive layer 6 is about, for example, 20 μm. The patterning resist film is then removed. Finally, by removing the copper thin film by using the conductive layer 6 as a mask, the conductive layer 6 in the first layer in the stack is formed on the insulating layer 4. As a result, both of the insulating layer 4 and the conductive layer 6 in the first layer in the stack are formed in the groove 3.

As shown in FIG. 3B, by pressure bonding a stacked film comprising the insulating layer 7 and a copper foil 8z to the assembly in which the conductive layer 6 in the first layer in the stack is formed, the insulating layer 7 having a thickness of about 80 μm and the copper foil 8z having a thickness of about 3 μm are formed. The material having the same composition as the insulating layer 4 is employed to form the insulating layer 7.

As shown in FIG. 3C, photolithography and etching are used to remove the copper foil 8z located where the via hole 7a (see FIG. 1) is formed. In this way, the area in the insulating layer 7 where the via hole 7a is formed is exposed.

As shown in FIG. 3D, the copper foil 8z is irradiated by CO₂ laser or UV laser from above so as to remove an area extending from the exposed surface of the insulating layer 7 to the surface of the conductive layer 6. In this way, the via hole 7a having a diameter of about 70 μm and running through the insulating layer 7 is formed.

As shown in FIG. 3E, electroless plating is used to plate the surface of the copper foil 8z and the interior of the via hole 7a with copper to a depth of about 0.5 μm. Subsequently, electroplating is used to plate the surface of the copper foil 8z and the interior of the via hole 7a with copper. In this embodiment, an inhibitor and an accelerator are added to the plating solution, so that the inhibitor is absorbed by the surface of the copper foil 8z and the accelerator is absorbed by the interior of the via hole 7a. This can enlarge the thickness of copper plating in the interior of the via hole 7a. Thereby, the via hole 7a is filled with copper. As a result, as shown in FIG. 3E, the conductive layer 8 having a thickness of about 15 μm is formed on the insulating layer 7 and the via hole 7a is filled with the conductive layer 8.

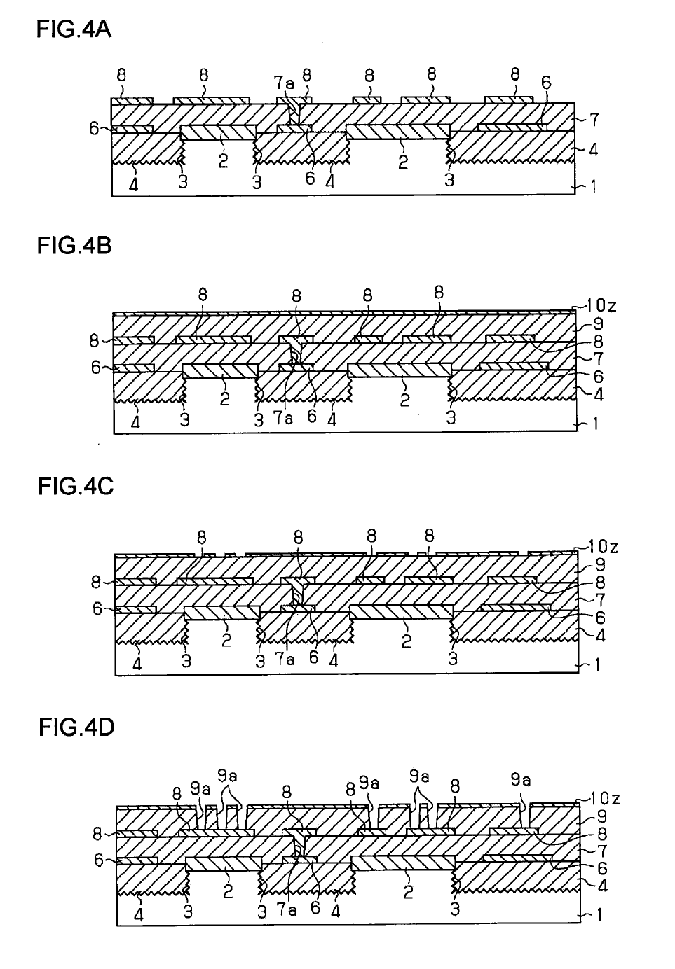

Subsequently, as shown in FIG. 4A, photolithography and etching are used to pattern the conductive layer 8. In this way, the conductive layer 8 having a predetermined wiring pattern is formed.

As shown in FIG. 4B, by subsequently pressure bonding a stacked film comprising the insulating layer 9 and a copper foil 10z to the assembly in which the conductive layer 8 in the second layer in the stack is formed, the insulating layer 9 having a thickness of about 80 μm and the copper foil 10z having a thickness of about 3 μm are formed. The material having the same composition as the insulating layer 4 is employed to form the insulating layer 9.

As shown in FIG. 4C, photolithography and etching are used to remove the copper foil 10z located where the via hole 9a (see FIG. 1) is formed. In this way, the area in the insulating layer 9 where the via hole 9a is formed is exposed.

As shown in FIG. 4D, the copper foil 10z is irradiated by CO₂ laser or UV laser from above so as to remove an area extending from the exposed surface of the insulating layer 9 to the surface of the conductive layer 8. In this way, the via hole 9a having a diameter of about 70 μm and running through the insulating layer 9 is formed.

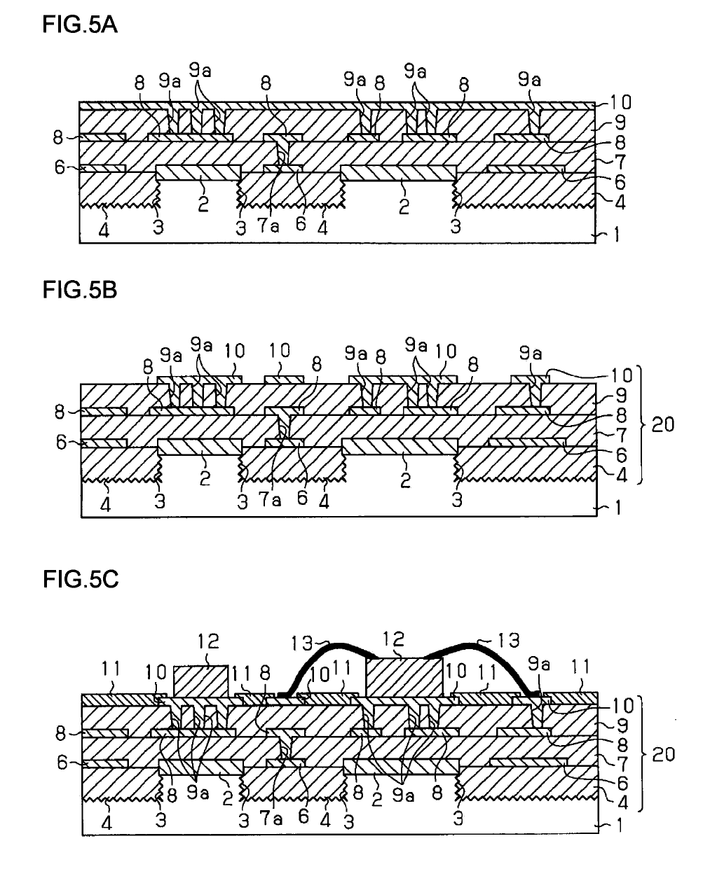

As shown in FIG. 5A, electroless plating is subsequently used to plate the surface of the copper foil 10z and the interior of the via hole 9a with copper to a depth of about 0.5 μm. Subsequently, electroplating is used to plate the top surface of the copper foil 10z and the interior of the via hole 9a. In this process, an inhibitor and an accelerator are added to the plating solution, so that the inhibitor is absorbed by the surface of the copper foil 10z and the accelerator is absorbed by the interior of the via hole 9a. This can enlarge the thickness of copper plating in the interior of the via hole 7a. Thereby, the via hole 9a is filled with copper. As a result, the conductive layer 10 having a thickness of about 15 μm is formed on the insulating layer 9 and the via hole 9a is filled with the conductive layer 10.

Subsequently, as shown in FIG. 5B, photolithography and etching are used to pattern the conductive layer 10. In this way, the conductive layer 10 having a predetermined wiring pattern is formed. The wiring layer 20, in which the insulating layers 4, 7 and 9 and the conductive layers 6, 8 and 10 are alternately stacked on each other, is formed on the metal substrate 1 and the heat transfer layer 2, which define the grooves 3.

As shown in FIG. 5C, the solder resist layer 11 is formed to cover the wiring layer 20 (insulating layer 9 and the conductive layer 10) and is formed to create openings at predetermined areas of the conductive layer 10 where the circuit elements are mounted or wires are connected. The thickness of the solder resist layer 11 is about, for example, 20 μm. The circuit element 12 is mounted on the conductive layer 10 via an adhesive layer (not shown) formed of an insulating material. The circuit element 12 is, for example, a semiconductor element such as an IC chip or an LSI chip, or a passive element such as a capacitor or a resistor. Subsequently, the wires 13 made of, for example, gold are used for electrical connection between the circuit elements 12 and the conductive layer 10 corresponding to the pad area.

Finally, the sealing resin layer 14 comprising epoxy resin is formed to cover the circuit element 12 mounted on the wiring layer 20 for the purpose of protecting the circuit element 12.

The circuit apparatus according to the first embodiment is produced through the steps described above.

The following advantages are provided by the circuit apparatus according to the first embodiment.

(1) By providing the heat transfer layer 2 with a higher heat conductivity than the metal substrate 1 below the circuit element 12, heat resistance is reduced in a path in which heat from the circuit element 12 is conducted to the metal substrate 1 through the wiring layer 20. Thus, heat from the circuit element 12 is efficiently conducted to the metal substrate 1 via the heat transfer layer 2, ensuring excellent heat dissipation from the circuit apparatus. Outside the area where the heat transfer layer 2 is provided, the surface of the metal substrate 1 in contact with the wiring layer 20 is turned into a roughened surface with minute irregularities. Thus, the area of contact between the metal substrate 1 and the wiring layer 20 (insulating layer 4) is increased. In this way, the intimacy of contact between the metal substrate 1 and the wiring layer 20 (insulating layer 4) is improved and the likelihood of exfoliation of the wiring layer 20 (insulating layer 4) from the metal substrate 1 is reduced. Consequently, heat dissipation of the circuit apparatus is improved, while reducing the likelihood of exfoliation of the insulating layer from the metal substrate.

(2) By providing the heat transfer layer 2 opposite to the conductive layers 6, 8 and 10 provided below the circuit element 12, heat generated from the circuit element 12 is conducted to the heat transfer layer 2 via the conductive layers 6, 8 and 10 provided below the circuit element 12. Thus, heat resistance is reduced in a path in which heat generated from the circuit element 12 is conducted to the metal substrate 1, thereby further improving heat dissipation.

(3) As the anchor effect is exhibited between the wiring layer 20 formed on the metal substrate 1 and the groove 3 formed by the metal substrate 1 and the heat transfer layer 2, the intimacy of contact between the metal substrate 1 and the wiring layer 20 is improved. The sides, as well as the bottom, of the groove 3 in the metal substrate 1 is roughened, the area of contact with the insulating layer 4 is increased in comparison with the case where the groove 3 is absent. In this way, the intimacy of contact between the metal substrate 1 and the insulating layer 4 is improved. Consequently, the advantage of reducing the likelihood of exfoliation of the wiring layer (insulating layer) from the metal substrate is further enhanced.

(4) By providing the conductive layer 8 opposite to the wiring layer 2, heat generated from the circuit element 12 is conducted to the heat transfer layer 2 via the conductive layer 8 provided below the circuit element 12 and is then conducted from the heat transfer layer 2 to the metal substrate 1. Accordingly, heat resistance is reduced in a path in which heat from the circuit element 12 is conducted to the metal substrate 1, thereby improving heat dissipation. By providing the lowermost conductive layer 6 opposite to the exposed area of the metal substrate 1, it is ensured that exfoliation at the interface between the metal substrate 1 and the insulating layer 4 is unlikely to occur in an area below the conductive layer 6 which is relatively removed from the circuit element 12 and to which only a limited amount of heat is conducted. Consequently, heat dissipation of the circuit apparatus is improved, while reducing the likelihood of exfoliation in the circuit apparatus.

(5) By providing at least a part of the lowermost conductive layer 6 in the groove 3, the conductive layer 6 is further removed from the circuit element 12 so that heat conduction from the circuit element 12 to the conductive layer 6 is further reduced and the likelihood of exfoliation at the interface between the metal substrate 1 and the insulating layer 4 is reduced. Consequently, the advantage of reducing the likelihood of exfoliation of the wiring layer (insulating layer) from the metal substrate is further enhanced.

(6) By embedding the conductive layer 6 in the groove 3 and ensuring that the conductive layer 8, which is provided below the circuit element 12, is opposite to the heat transfer layer 2, the number of conductive layers provided above the heat transfer layer 2 is reduced by one, thereby reducing the substantial thickness of the wiring layer. Accordingly, the thickness of the circuit apparatus is reduced. Since the path of heat dissipation from the conductive layer 8, which is provided below the circuit element 12, to the heat transfer layer 2 is reduced, heat dissipation is further promoted.

(7) The heat transfer layer 2 (partitioned heat transfer layer) provided for each circuit element 12 and below the element helps heat to be dissipated to the metal substrate 1. Further, since the heat transfer layer 2 is partitioned to correspond to respective circuit elements 12, the ratio between the area occupied by the heat transfer layer 2 and the surrounding roughened area can be easily controlled according to the amount of heat generated by the respective circuit elements 12. Accordingly, the likelihood of exfoliation of the wiring layer (insulating layer) from the metal substrate is effectively reduced.

(Variation)

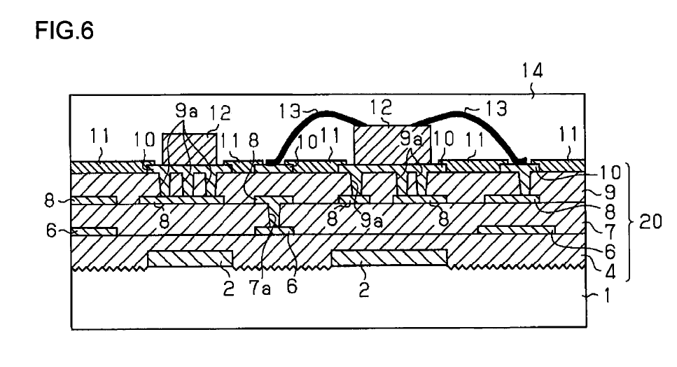

FIG. 6 is a schematic sectional view of a circuit apparatus according to a variation of the first embodiment. The difference from the first embodiment is that the groove is not formed in the metal substrate 1. The other aspects of the apparatus are the same as the corresponding aspects of the first embodiment.

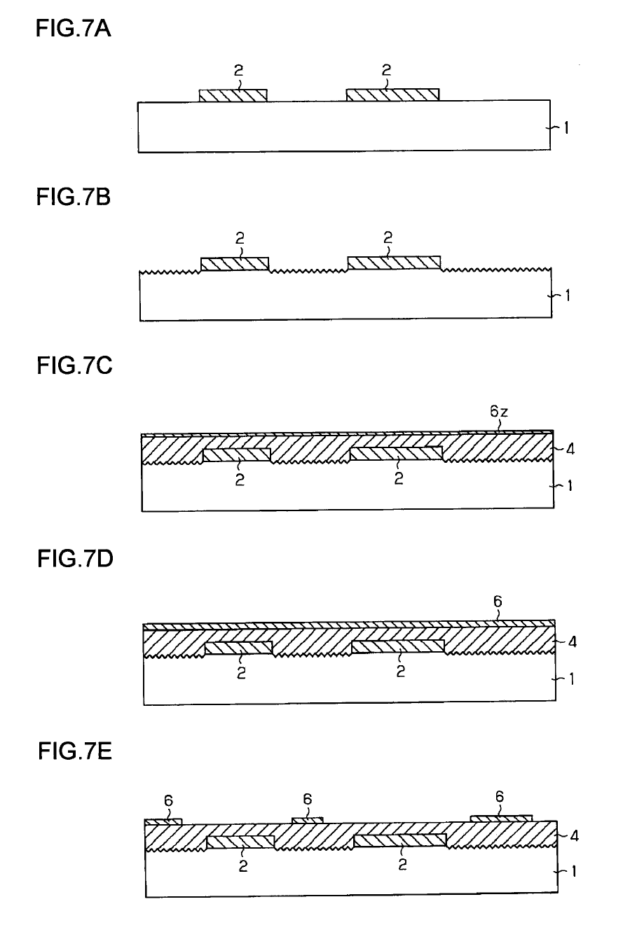

FIGS. 7A-7E are sectional views for illustrating the process for fabricating the circuit apparatus according to the variation of the first embodiment.

A stack structure as shown in FIG. 2A comprising the metal substrate 1 and the heat transfer layer 2 is prepared. As shown in FIG. 7A, lithography is used to form a patterning resist film (not shown) on the surface of the heat transfer layer 2 such that openings (areas corresponding to the grooves 3 of the above-described embodiment) are created. The heat transfer layer 2 is then etched by using the patterning resist film as a mask so as to expose the surface of the metal substrate 1. The heat transfer layer 2 is partitioned such that the circuit element is mounted in each resultant area. The exposed area of the metal substrate 1 is formed to surround the heat transfer layer 2.

As shown in FIG. 7B, the surface of the metal substrate 1 is roughened by, for example, wet etching.

As shown in FIG. 7C, by pressure bonding a stacked film comprising the insulating layer 4 and a copper foil 6z so as to cover the metal substrate 1 and the heat transfer layer 2, the insulating layer 4 having a thickness of about 80 μm and the copper foil 6z having a thickness of about 3 μm are formed. The material having the same composition as that of the above-described embodiment is employed to form the insulating layer 4.

As shown in FIG. 7D, electroless plating and electroplating are used to plate copper and form the conductive layer 6 accordingly. The thickness of the conductive layer 6 is about, for example, 20 μm.

Subsequently, as shown in FIG. 7E, photolithography and etching are used to pattern the conductive layer 6. In this way, the conductive layer 6 in the first layer in the stack having a predetermined wiring pattern is formed.

The steps for fabricating the second and subsequent layers are the same as those of FIG. 3B and subsequent figures. The circuit apparatus according to the variation of the first embodiment is produced through the steps described above.

The same advantages as described in (1), (2) and (4) with respect to the first embodiment are also enjoyed with the circuit apparatus according to the variation.

In the first embodiment, a single-layer copper substrate is used as the metal substrate 1. Alternatively, the metal substrate 1 may be formed of clad laminates comprising a lowermost metal layer formed of copper, an intermediate metal layer of an Fe—Ni based copper (invar alloy) formed on the lowermost metal layer, and an uppermost metal layer of copper formed on the intermediate metal layer. In this case, the coefficient of thermal expansion of the stacked metal substrate can be controlled by adjusting the thickness of the lowermost metal layer, the intermediate metal layer and the uppermost metal layer. By controlling the thickness of the metal layers so that the coefficient of thermal expansion of the metal substrate approaches the coefficient of thermal expansion of the insulating layer, the likelihood of exfoliation of the wiring layer (insulating layer) from the metal substrate due to a difference in coefficient of thermal expansion between the metal substrate and the insulating layer is reduced.

In the first embodiment, the wiring layer 20 of a three-layer structure is described by way of example. Alternatively, the embodiment is equally applicable to wiring layer having a two-layer structure or a structure with four or more layers.

In the above-described embodiment, the bottom and the sides of the groove 3 in the metal substrate 1 are roughened. The advantage of the embodiment will equally be enjoyed by roughening only one of the bottom and the sides since it will also increase the area of contact between the metal substrate and the wiring layer (insulating layer).

In the above-described embodiment, the conductive layer 6 is located in the groove 3 above the interface between the metal substrate 1 and the heat transfer layer 2. Alternatively, the entirety of the conductive layer 6 may be located below the interface between the metal substrate 1 and the heat transfer layer 2 (i.e., in the area of the groove adjacent to the metal substrate 1). In this case, heat conduction from the circuit element 12 to the conductive layer 6 is further reduced so that the advantage of reducing the likelihood of exfoliation of the wiring layer (insulating layer) from the metal substrate is further promoted.

### Second Embodiment

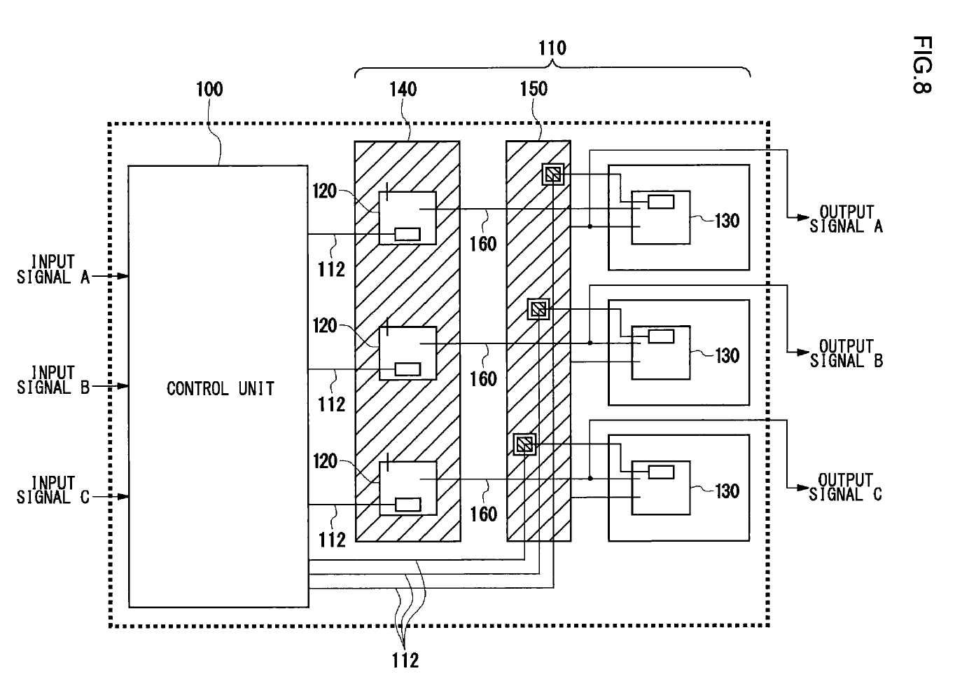

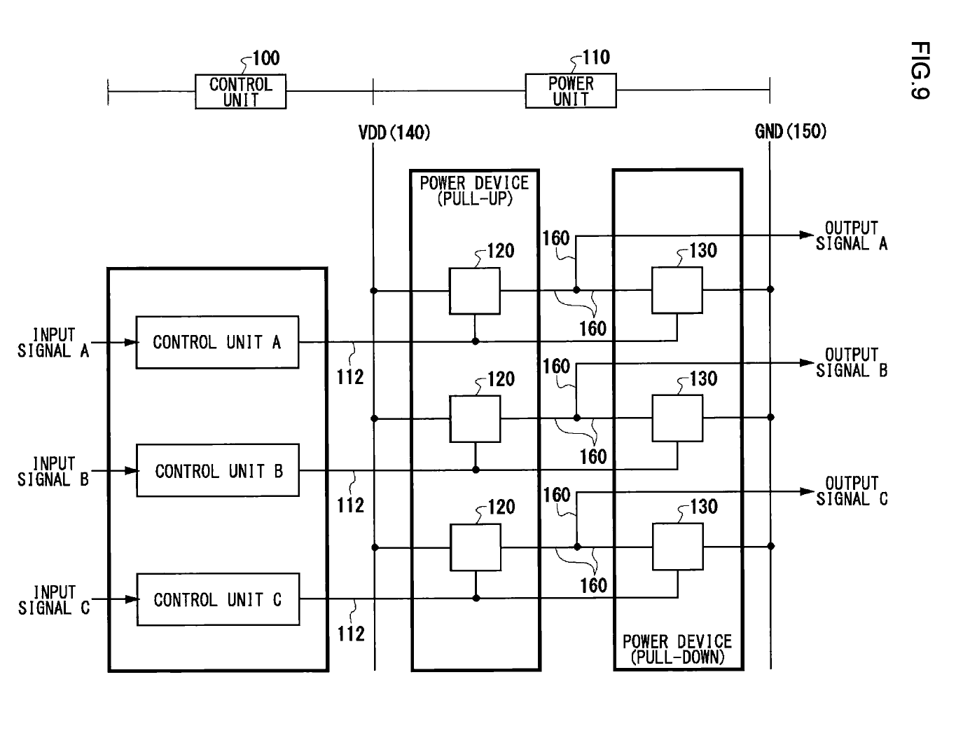

FIG. 8 is a top view showing the layout of a control unit and a power unit of a circuit apparatus according to a second embodiment. FIG. 9 is an equivalent circuit diagram related to the control unit and the power unit of the circuit apparatus according to the second embodiment.

As shown in FIGS. 8 and 9, the circuit apparatus according to the second embodiment comprises a control unit 100 and a power unit 110.

The control unit 100 generates a control signal on the basis of input signals A-C and outputs the control signal thus generated to the power unit 110. Preferably, the control unit 100 is of a configuration capable of advanced control for quiet operation and reduction in power consumption. Specifically, the control unit 100 is provided with circuit elements fabricated in a CMOS microfabrication process such as a signal processor, a RAM and a flash memory. The power supply voltage of the control unit 100 is in the range 1.5-3.0V, indicating that the amount of heat generated is relatively low. A power device driving unit for amplifying a signal for driving the power device constituting the power unit 110 may be provided between the control unit 100 and the power unit 110. The power device driving unit may be included in the control unit 100.

The power control unit 110 comprises a power device 120 and a power device 130. The power device 120 pulls up the output signal to VDD. The power device 130 pulls down the output signal to GND. The power device 120 and the power device 130 are required to have sufficient driving capability to drive a load such as a fan motor efficiently. In this respect, a discrete device such as a MOS transistor, a bipolar transistor or an insulated gate bipolar transistor is suitably used as the power device 120 and the power device 130. As shown in FIG. 9, control units A-C each comprising a plurality of circuit elements are provided in the control unit 100 for respective pairs of the power device 120 and the power device 130. Predetermined control signals are transmitted to the respective pairs of the power device 120 and the power device 130 in accordance with input signals A-C.

The power device 120 and the power device 130 generate much Joule heat if the load imposed by a device to be driven is large. Thus, the power device 120 and the power device 130 generate more heat than the circuit elements constituting the control unit 100. That is, the circuit elements constituting the control unit 100 represent low heat dissipation circuit elements generating relatively less heat. Meanwhile, the power device 120 and the power device 130 represent high heat dissipation elements generating relatively more heat.

A description will now be given of a case where the power device is an N-type MOS transistor. Input lines for transmitting the control signals from the control unit 100 are connected to the gates of the respective power devices 120 and 130. The drains of the power devices 120 are connected to a VDD line (power supply line) 140. The sources of the power devices 130 are connected to the GND line (ground line) 150. The sources of the power devices 120 and the drains of the power devices 130 are connected to an output line 160. The output line 160 is connected to, for example, a load circuit (not shown) so that the load circuit is driven in accordance with the logical level (output signals A-C) output from the power unit 110. More specifically, when the control signal transmitted by the input line 112 causes the gate level of the power device 120 to be “high (on)” and the gate level of the power device 130 to be “low (off)”, the control signal transmitted from the output line 160 is logically “high”. Conversely, when the control signal transmitted by the input line 112 causes the gate level of the power device 120 to be “low” and the gate level of the power device 130 to be “high”, the control signal transmitted from the output line 160 is logically “low”.

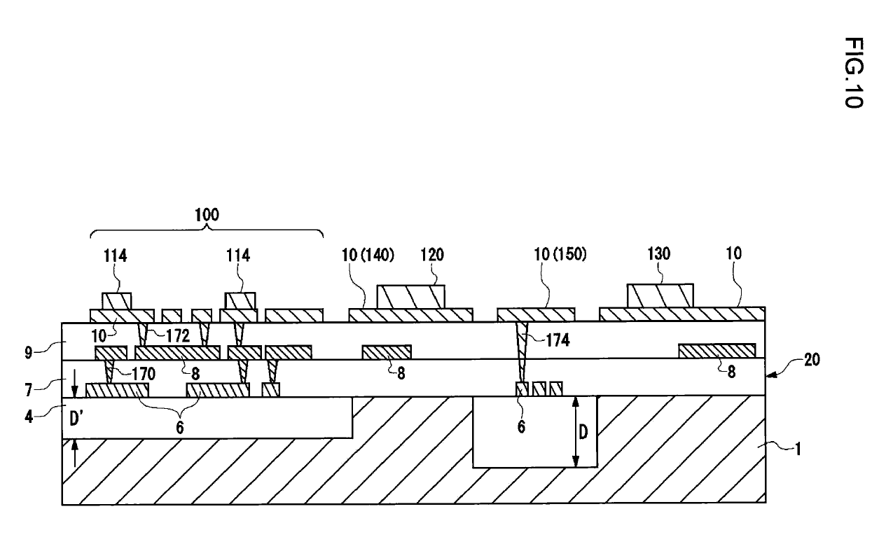

FIG. 10 is a sectional view showing the schematic sectional structure of the circuit apparatus according to the second embodiment. As shown in FIG. 10, the circuit apparatus according to the second embodiment is configured such that the wiring layer 20 is formed on the metal substrate 1, and the power device 120 and the power device 130 are mounted on the wiring layer 20 in addition to the circuit element 114 constituting the control unit 100.

Steps are formed by grooves of a predetermined pattern on the primary surface of the metal substrate 1. The depth of the grooves provided on the primary surface of the metal substrate 1 depends on the amount of heat generated by the circuit element mounted above. More specifically, circuit elements generating more heat (i.e., the power device 120 and the power device 130) are mounted above projections on the metal substrate 1. The circuit element 114 generating less heat is mounted above the depression in the metal substrate 1. In other words, the distance between the power device 120 or the power device 130, which generates a relatively large amount of heat, and the metal substrate 1 part opposite to the device is smaller than the distance between the circuit element 114 of the control unit 100, which generates a relatively small amount of heat, and the metal substrate 1 part opposite to the element 114.

According to this provision, the power device 120 and the power device 130 are provided at relatively close distance from the metal substrate 1, ensuring that heat generated by the power device 120 and the power device 130 is more efficiently conducted to the metal substrate 1 and thereby improving heat dissipation of the circuit apparatus.

The circuit apparatus according to the second embodiment is configured such that the wiring layer 20 is of a three-layer structure in which the insulating layers 4, 7 and 9 and the conductive layers 6, 8 and 10 are alternately stacked on each other. The conductive layer 6 and the conductive layer 8 are connected to each other via a via hole 170 provided at a predetermined location. The conductive layer 8 and the conductive layer 10 are connected to each other via a via hole 172 provided at a predetermined location. The circuit element 114 is mounted on the conductive layer 10. The ground line 150 and the conductive layer 160 are electrically connected via a via 174 running through the insulating layers 7 and 9.

In contrast, the power device 120 and the power device 130 are mounted on the conductive layer 10. The wiring layer 20, located between each of the power devices 120 and 130, and the metal substrate 1, comprises the conductive layer 10, the insulating layers 7 and 9. That is, the number of wiring layers, each comprising a conductive layer and an insulating layer formed between the metal substrate 1 and each of the power device 120 and the power device 13, is smaller than the number of wiring layers each comprising a conductive layer and an insulating layer formed between the circuit device 114 and the metal substrate 1. This reduces the distance between the metal substrate 1 and each of the power device 120 and the power device 130. Accordingly, heat resistance is reduced. This ensures that heat generated by the power devices 120 and 130 is efficiently conducted to an area in the metal substrate opposite to the power devices 120 and 130. The conductive layer 10 on which the power device 120 is mounted is a power supply line 140.

In this embodiment, the distance between the circuit element 114 and the metal substrate 1 is smaller than that between the ground line 150 and the metal substrate 1. More specifically, the depth D′ of the groove in area of the metal substrate 1 opposite to the circuit element 114 is smaller than the depth D of the groove in an area of the metal substrate 1 opposite to the ground line 150. The depth can be set such that the electric field strength occurring when a high voltage is applied to the conductive layer is not sufficient to produce discharge from the conductive layer to the metal substrate. Thus, the likelihood of discharge to the metal substrate 1 is reduced. Consequently, heat dissipation of the circuit apparatus is improved.

The depth D′ of the groove in area of the metal substrate 1 opposite to the circuit element 114 may be equal to the depth D of the groove in area of the metal substrate 1 opposite to the ground line 150. This can simplify the process for fabricating the circuit apparatus since the grooves can be formed in the metal substrate 1 in a single etching step.

It is also favorable that the primary surface of the metal substrate 1 be roughened. In this way, the area of contact between the metal substrate 1 and the insulating layers 4 and 7 is increased. With this, the intimacy of contact between the metal substrate 1 and the insulating layer 4 and 7 is improved and the likelihood of exfoliation of the insulating layers 4 and 7 from the metal substrate 1 is reduced. Consequently, a circuit apparatus is provided in which heat dissipation is improved while the likelihood of exfoliation of the insulating layers 4 and 7 from the metal substrate 1 is reduced.

What is claimed is:

1. A circuit apparatus comprising:
a metal substrate the primary surface of which is provided with a step;
a conductive layer provided on the primary surface of the metal substrate via an insulating layer; and
a plurality of circuit elements provided on the conductive layer and generating different amounts of heat, wherein
the distance between the high heat dissipation circuit element generating a relatively large amount of heat and an area in the metal substrate opposite to the high heat dissipation circuit element is smaller than the distance between the low heat dissipation circuit element generating a relatively small amount of heat and an area in the metal substrate opposite to the low heat dissipation circuit element.

2. The circuit apparatus according to claim 1, wherein
the number of wiring layers, each comprising a conductive layer and an insulating layer formed between the high dissipation circuit element and the metal substrate opposite to the high heat dissipation circuit element, is smaller than the number of wiring layers each comprising a conductive layer and an insulating layer formed between the low heat dissipation circuit element and the metal substrate opposite to the low heat dissipation circuit element.

3. The circuit apparatus according to claim 1, wherein the surface of the metal substrate is roughened.

4. The circuit apparatus according to claim 2, wherein the surface of the metal substrate is roughened.

5. The circuit apparatus according to claim 1, wherein the high heat dissipation circuit element is a power device for supplying power to a load and the low heat dissipation element controls the output of the power device or drives the power device.

6. The circuit apparatus according to claim 2, wherein the high heat dissipation circuit element is a power device for supplying power to a load and the low heat dissipation element controls the output of the power device or drives the power device.

7. The circuit apparatus according to claim 3, wherein the high heat dissipation circuit element is a power device for supplying power to a load and the low heat dissipation element controls the output of the power device or drives the power device.

8. The circuit apparatus according to claim 4, wherein the high heat dissipation circuit element is a power device for supplying power to a load and the low heat dissipation element controls the output of the power device or drives the power device.
